(19) United States
(12) Patent Application Publication
(10) Pub. No.: US 2008/0303603 A1
(43) Pub. Date: Dec. 11, 2008

(54) SEMICONDUCTOR INTEGRATED CIRCUIT DEVICE

(75) Inventors: Shouhei KOUSAI, Yokohama-Shi (JP); Daisuke Miyashita, Kawasaki-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/133,589

(22) Filed: Jun. 5, 2008

(30) Foreign Application Priority Data
Jun. 6, 2007 (JP) 2007-149981

(51) Int. Cl. H03L 7/085

(52) U.S. Cl. 331/36 C; 331/34; 331/186

(57) ABSTRACT

A semiconductor integrated circuit device includes a voltage controlled oscillator which controls a bias current or an oscillation frequency to supply an output signal, a phase-locked loop circuit which supplies a frequency control signal based on the output signal supplied from the voltage controlled oscillator, a peak detection circuit which detects a peak of the frequency control signal supplied from the phase-locked loop circuit, and a bias control circuit which produces a bias current based on the peak detected by the peak detection circuit to supply the bias current. The voltage controlled oscillator controls the bias current supplied from the bias control circuit or the oscillation frequency to supply the output signal based on the frequency control signal supplied from the phase-locked loop circuit.

### CROSS-REFERENCE TO RELATED APPLICATIONS

This application is based upon and claims the benefit of priority from the prior Japanese Patent Application No. 2007-149981, filed on Jun. 6, 2007; the entire contents of which are incorporated herein by reference.

### BACKGROUND OF THE INVENTION

The present invention relates to a semiconductor integrated circuit device, particularly to a semiconductor integrated circuit device provided with a bias control circuit which reduces a phase noise.

Conventionally, a general semiconductor integrated circuit device includes a Voltage Controlled Oscillator (VCO) and a Phase-Locked Loop (PLL) circuit. VCO controls an oscillation frequency based on a control voltage. PLL circuit performs feedback on a VCO output signal (VCO output) and a frequency control signal indicating a frequency phase difference of a reference signal to VCO.

Particularly, a radio communication apparatus (for example, portable telephone) includes VCO which controls the oscillation frequency on the basis of a voltage applied from the outside in radio signal processing. The stable VCO output is required in VCO of the radio communication apparatus.

However, in the conventional VCO, a phase noise is increased to destabilize the VCO output by oscillation frequency amplitude of VCO or a change in steady-state current fed into VCO, which results in a problem in that performance of the semiconductor integrated circuit device is deteriorated.

On the other hand, for example, Japanese Patent Application Laid-Open Publication No. 2006-197571 discloses a semiconductor integrated circuit device which reduces the phase noise. The semiconductor integrated circuit device includes a maximum value detection circuit which detects a maximum value of the oscillation frequency amplitude and a minimum value detection circuit which detects a minimum value of the oscillation frequency. The semiconductor integrated circuit device performs control on the basis of the detection result such that the oscillation frequency amplitude of VCO is equalized to an amplitude of a threshold voltage (Vth) of a transistor.

However, although the semiconductor integrated circuit device disclosed in Japanese Patent Application Laid-Open Publication No. 2006-197571 includes means for reducing the phase noise caused by the oscillation frequency amplitude of VCO, the semiconductor integrated circuit device does not include means for reducing the phase noise caused by the change in steady-state current fed into VCO. A degree in which the phase noise caused by the change in steady-state current fed into VCO is deteriorated is larger than a degree in which the phase noise caused by the oscillation frequency amplitude of VCO is deteriorated. Additionally, because a condition that the phase noise becomes the minimum varies from VCO to VCO, sometimes the phase noise of VCO is not reduced by the means disclosed in Japanese Patent Application Laid-Open Publication No. 2006-197571.

Therefore, in the conventional semiconductor integrated circuit device, the phase noise of VCO cannot be reduced to stabilize the VCO output.

### SUMMARY OF THE INVENTION

According to the first aspect of the invention, there is provided that a semiconductor integrated circuit device comprising:

a voltage controlled oscillator which controls a bias current or an oscillation frequency to supply an output signal;

a phase-locked loop circuit which supplies a frequency control signal based on the output signal supplied from the voltage controlled oscillator;

a peak detection circuit which detects a peak of the frequency control signal supplied from the phase-locked loop circuit; and

a bias control circuit which produces a bias current based on the peak detected by the peak detection circuit to supply the bias current,

wherein the voltage controlled oscillator controls the bias current supplied from the bias control circuit or the oscillation frequency to supply the output signal based on the frequency control signal supplied from the phase-locked loop circuit.

According to the second aspect of the invention, there is provided that a semiconductor integrated circuit device comprising:

a voltage controlled oscillator which controls a bias current or an oscillation frequency to supply an output signal based on a constant frequency control signal;

a frequency counter which measures an oscillation frequency of the output signal supplied from the voltage controlled oscillator;

a peak detection circuit which detects a peak of the output signal based on a counted value supplied from the frequency counter; and

a bias control circuit which produces a bias current based on the peak detected by the peak detection circuit to supply the bias current,

wherein the voltage controlled oscillator controls the bias current or oscillation frequency to supply the output signal based on the bias current supplied from the bias control circuit.

### BRIEF DESCRIPTION OF THE DRAWINGS

FIG. 1 is a circuit diagram showing a configuration of LC-VCO which is an example of a Voltage Controlled Oscillator (VCO) according to a first embodiment of the invention.

FIGS. 2(a) to 2(d) are graphs showing a relationship between a bias current I and Cn, Cp, Cv, and a total capacity Ct (=Cn+Cp+Cv).

FIG. 3 is a block diagram showing a configuration of a semiconductor integrated circuit device 300 of the first embodiment of the present invention.

FIG. 4 is a circuit diagram showing a configuration of a switched capacitor comparator which is of an example of a peak detection circuit 303 of the first embodiment of the present invention.

FIG. 5 is a block diagram showing a configuration of a radio communication system 500 provided with the semiconductor integrated circuit device 300 of the first embodiment of the present invention.

FIG. 6 is a circuit diagram showing a configuration of LC-VCO which is an example of VCO 801 according to a second embodiment of the invention of the present invention.

FIG. 7 is a graph showing a relationship between a total capacity Ct and a bias current I and a relationship between a phase noise of VCO and the bias current I when a capacity gradient control device 605 formed by a MOS varactor of the second embodiment of the present invention is used.

FIG. 8 is a block diagram showing a configuration of a semiconductor integrated circuit device 800 of the second embodiment of the present invention.

FIG. 9 is a circuit diagram showing a configuration of LC-VCO which is an example of VCO according to a third embodiment of the invention of the present invention.

FIG. 10 is a graph showing a relationship between a bias current I and a total capacity Ct corresponding to back-gate voltages of capacity gradient control signals 1001 to 1003.

FIG. 11 is a block diagram showing a configuration of a semiconductor integrated circuit device 1100 according to a fourth embodiment of the present invention.

### DETAILED DESCRIPTION OF THE INVENTION

Exemplary embodiments of the present invention will be described below. The embodiments of the present invention are illustrated only by way of example, and the embodiments of the present invention are not intended to limit the scope of the invention.

### First Embodiment

In a first embodiment of the present invention, an example in which a VCO phase noise caused by a noise of a current source is reduced will be described below.

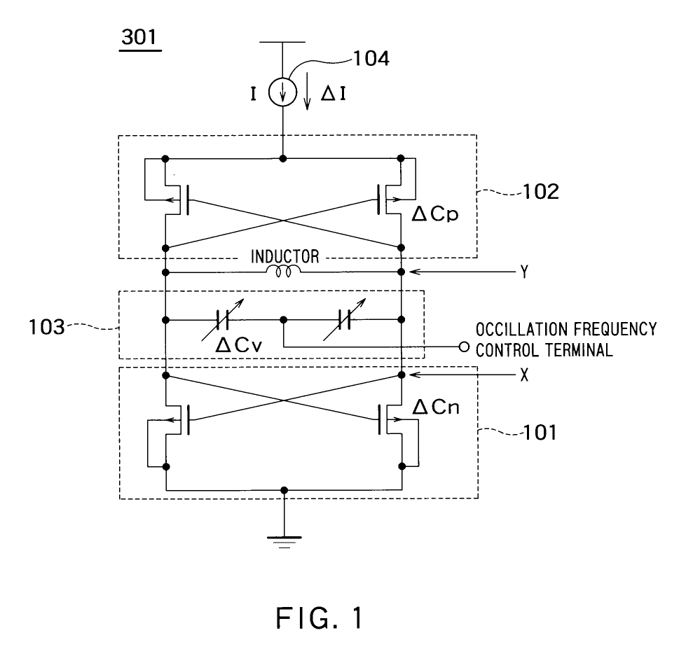

FIG. 1 is a circuit diagram showing a configuration of LC-VCO which is an example of a Voltage Controlled Oscillator (VCO) according to a first embodiment of the invention.

VCO of the first embodiment includes an NMOS transistor pair 101, a PMOS transistor pair 102, a varactor 103, and a current source 104. A capacity of the varactor 103 is controlled by an inductor and an oscillation frequency control terminal.

An influence of a noise (change in steady-state current) of the current source 104 on the phase noise of VCO will be described below.

Assuming that Cn, Cp, and Cv are capacities of the NMOS transistor pair 101, PMOS transistor pair 102, and varactor 103 and L is inductance of the inductor, an oscillation frequency FVCO of LC-VCO is expressed by Formula 1:

$${F}_{V C O} = \frac{1}{2 π \sqrt{L ( Cn + Cp + Cv )}} \qquad [ Formula 1 ]$$

At this point, when a noise ΔI exists in a current source, potentials fluctuate at an X point (NMOS gate) and a Y point (PMOS gate) of FIG. 1 according to a fluctuation in current (ΔI). The fluctuation in potential causes fluctuations of Cn, Cp, and Cv. Assuming that ΔCn, ΔCp, and ΔCv are fluctuation amounts of Cn, Cp, and Cv, a post-fluctuation oscillation frequency F′VCO is expressed in the form of Fvco+ΔFvco by Formula 2:

$$\begin{matrix}{F}_{V C O}^{′} = {F}_{V C O} + Δ {F}_{V C O} \\ = \frac{1}{2 π \sqrt{L ( Cn + Cp + Cv + Δ Cn + Δ Cp + Δ Cv ) }}\end{matrix} \qquad [ Formula 2 ]$$

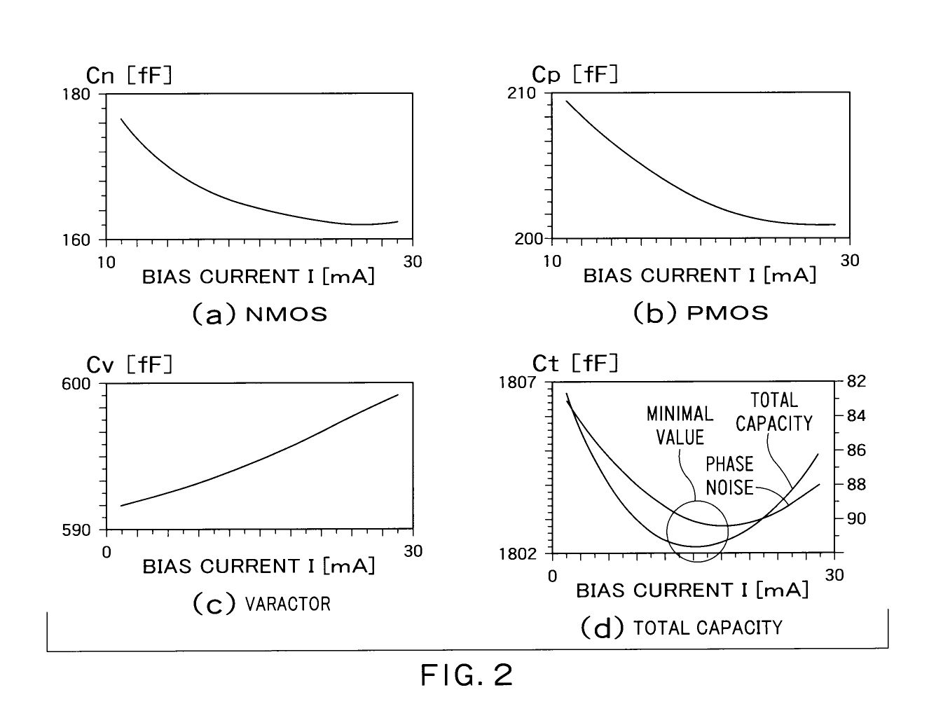

FIGS. 2(a) to 2(d) are graphs showing a relationship between a bias current I and Cn, Cp, Cv, and a total capacity Ct (=Cn+Cp+Cv) thereof. As shown in FIGS. 2(a) and 2(b), Cn and Cp are decreased as the bias current I is increased, and change amount of Cn and Cp are decreased as the bias current I is increased. On the other hand, as shown in FIG. 2(c), Cv is increased as the bias current I is increased. As a result, as shown in FIG. 2(d), Ct becomes a downwardly convex curve having a minimum value. Even if the noise ΔI exists in the bias current I corresponding to the minimum value, the oscillation frequency does not fluctuate because Ct does not fluctuate (because ΔCt (=ΔCn+ΔCp+ΔCv) is kept constant). That is, the noise ΔI of the bias current I does not contribute to the phase noise.

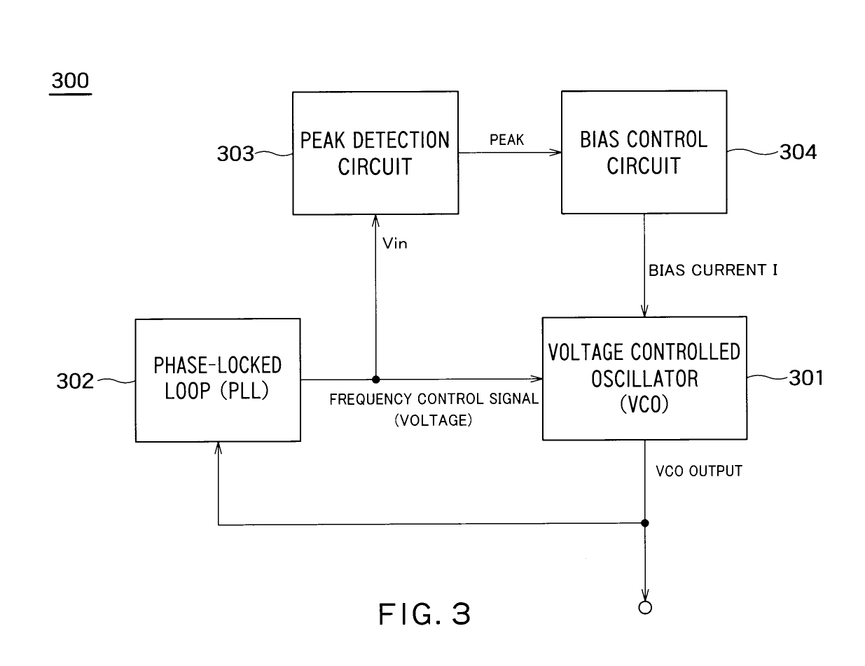

FIG. 3 is a block diagram showing a configuration of a semiconductor integrated circuit device 300 of the first embodiment of the present invention.

The semiconductor integrated circuit device 300 of the first embodiment of the present invention includes a Voltage Controlled Oscillator (VCO) 301, a Phase-Locked Loop (PLL) circuit 302, a peak detection circuit 303, and a bias control circuit 304.

An operation of the semiconductor integrated circuit device 300 of the first embodiment of the present invention will be described.

The bias control circuit 304 sets a bias current I of VCO 301 to a predetermined small value and supplies the bias current I. The PLL circuit 302 supplies a frequency control signal (voltage) to VCO 301 on the basis of a reference clock such that the oscillation frequency of VCO 301 is kept constant. The peak detection circuit 303 retains a frequency control signal value (Vin) supplied from the PLL circuit 302.

Then, the bias control circuit 304 slightly increases the bias current I of VCO 301 and supplies the bias current I. In response to the slightly-increased bias current I, the capacity of VCO 301 fluctuates as described above (see FIG. 2). The PLL circuit 302 supplies a new frequency control signal to control a variable capacity of VCO 301 such that the fluctuation in capacity of VCO 301 is cancelled to keep the oscillation frequency constant. The peak detection circuit 303 compares the new frequency control signal value (Vin′) and the previously retained frequency control signal value (Vin), and the peak detection circuit 303 makes a determination of the peak of the frequency control signal based on the comparison result.

Then, the bias control circuit 304 increases the bias current I again on the basis of the peak detected by the peak detection circuit 303. At this point, the determination result of the peak detection circuit 303 is inverted on reaching a point (peak) at which a capacity gradient becomes zero with respect to the bias current I. The bias control circuit 304 fixes the bias current I at the peak and supplies the bias current I.

The case in which VCO 301 has a relationship between the bias current I and the capacity as shown in FIG. 2 while the capacity Cv of the varactor 103 is decreased with increasing frequency control signal will be described below.

Because Ct is decreased when the bias control circuit 304 increases the bias current I, the PLL capacity 302 decreases the frequency control signal to increase Cv. As a result, the peak detection circuit 303 obtains the determination result of “decrease”.

However, Ct is increased when the bias control circuit 304 further increases the bias current I, the PLL circuit 302 increases the frequency control signal to decrease Cv. As a result, the peak detection circuit 303 obtains the determination result of “increase”.

The above description can be applied to not only LC-VCO but also other VCOs (for example, RING-VCO). VCO 301 may be configured to control not only the oscillation frequency of the output signal but also the bias current I of the bias control circuit 304.

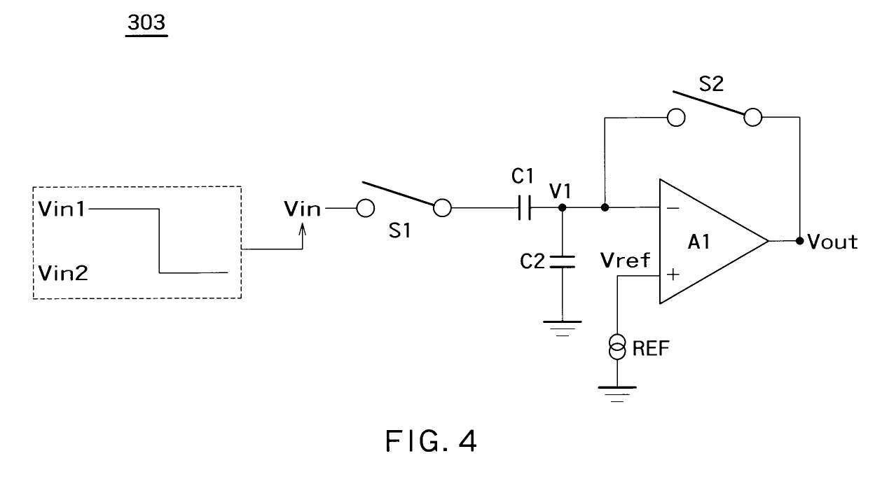

FIG. 4 is a circuit diagram showing a configuration of a switched capacitor comparator which is of an example of the peak detection circuit 303 of the first embodiment of the present invention.

The peak detection circuit 303 of the first embodiment of the present invention includes switches S1 and S2, an amplifier A1, capacitors C1 and C2, and a reference voltage source REF. For example, the switch S1 may be formed by a MOS transistor, and the capacitor C2 may be replaced by a parasitic capacity of the amplifier A1 or switch S2.

The peak detection circuit 303 closes the switches S1 and S2, and a predetermined voltage Vin1 is fed as an input voltage Vin (frequency control signal value).

At this point, because the switch S2 is closed, a negative input terminal and an output terminal of the amplifier A1 is short-circuited. As a result, an input voltage of the amplifier A1 is fixed to a voltage (reference voltage) Vref at the reference voltage source REF by a feedback effect of the amplifier A1. A charge corresponding to Vin−Vref is accumulated in the capacitor C1. For example, in the case of Vin−Vref>0 and Vref>0, a positive charge is accumulated in an electrode on a left side of the capacitor C1 while a negative charge is accumulated in an electrode on a right side of the capacitor C1. The positive charge corresponding to the voltage Vref at the reference voltage source REF is accumulated in an electrode on an upper side of the capacitor C2. A value of the voltage Vin1 is retained in this state.

Then, the switches S1 and S2 are opened. Only the switch S1 is closed after the input voltage Vin is changed from the voltage Vin1 to a voltage Vin2. At this point, the charge fluctuates in the left electrode of the capacitor C1. In the case where the voltage Vin2 is smaller than the voltage Vin1, the positive charge is decreased in the left electrode of the capacitor C1. In response to the decreased charge in the left electrode, the same amount of negative charge in the right electrode of the capacitor C1 is moved to the capacitor C2, the charge is decreased in the upper electrode of the capacitor C2, and the negative input voltage V1 at the amplifier A1 becomes smaller than the positive input voltage Vref. As a result, because the negative input voltage V1 is smaller than the positive input voltage Vref, the amplifier A1 amplifies the fluctuation in potential, and an output signal Vout of the amplifier A1 is set to an “H” level.

In the case where the voltage Vin2 is retained, the switch S2 is closed. In the case where the comparison is further continued, the switch S1 is closed after the switch S1 is opened to cause the input voltage Vin to fluctuate. In the case where the compared value is smaller than the retained value, the output signal Vout of the amplifier A1 becomes the “H” level. In the case where the compared value is larger than the retained value, the output signal Vout of the amplifier A1 becomes the “L” level.

The above description can be applied to not only the switched capacitor circuit but also other circuits (for example, a combination of an AD converter and a memory).

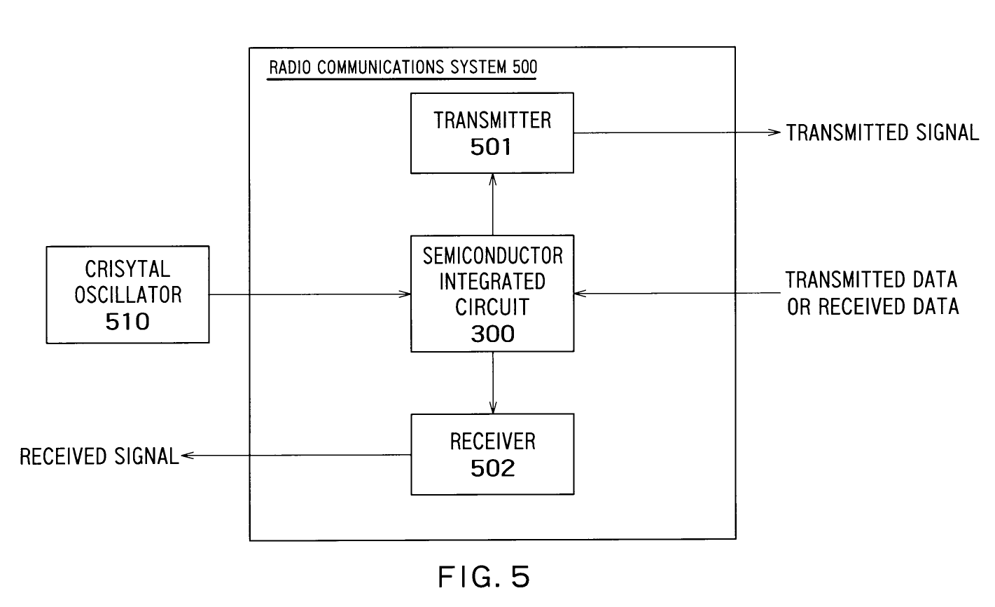

FIG. 5 is a block diagram showing a configuration of a radio communication system 500 (LSI for a radio communication device) provided with the semiconductor integrated circuit device 300 of the first embodiment of the present invention.

The radio communication system 500 includes a transmitter 501 and a receiver 502 in addition to the semiconductor integrated circuit device 300 of the first embodiment of the present invention, and the radio communication system 500 is connected to a quartz oscillator 510 which supplies a reference clock to the semiconductor integrated circuit device 300.

When the radio communication system 500 supplies transmitted data (for example, sound data) in the form of a transmitted signal (radio signal), the semiconductor integrated circuit device 300 supplies the fed transmitted data to the transmitter 501, and the transmitter 501 modulates the transmitted data to supply the transmitted data in the form of a transmitted signal (radio signal).

On the other hand, the radio communication system 500 supplies received data (for example, image data) in the form of a received signal (radio signal), the semiconductor integrated circuit device 300 supplies the received data to the receiver 502, and the receiver 502 modulates the received data to supply the received data in the form of a received signal (radio signal).

Thus, in the first embodiment of the present invention, the bias control circuit 304 controls VCO 301 while fixing the bias current at the peak detected by the peak detection circuit 303, so that the phase noise of VCO 301 caused by the noise of the current source 104 can be reduced to stabilize the VCO output.

The noise generated by a noise generating element except for the current source 104 is relatively reduced as the bias current supplied from the bias control circuit 403 to increase the oscillation frequency amplitude of VCO 301. Therefore, the noise generated by the noise generating element for the current source 104 has a little influence on performance of the semiconductor integrated circuit device.

### Second Embodiment

A second embodiment of the present invention will be described below. In the first embodiment of the present invention, the VCO phase noise caused by the noise of the current source is reduced. On the other hand, in the second embodiment of the present invention, the VCO phase noise caused by the noise generated by the noise generating element except for the current source is reduced. The same description as the first embodiment of the present invention is not repeated.

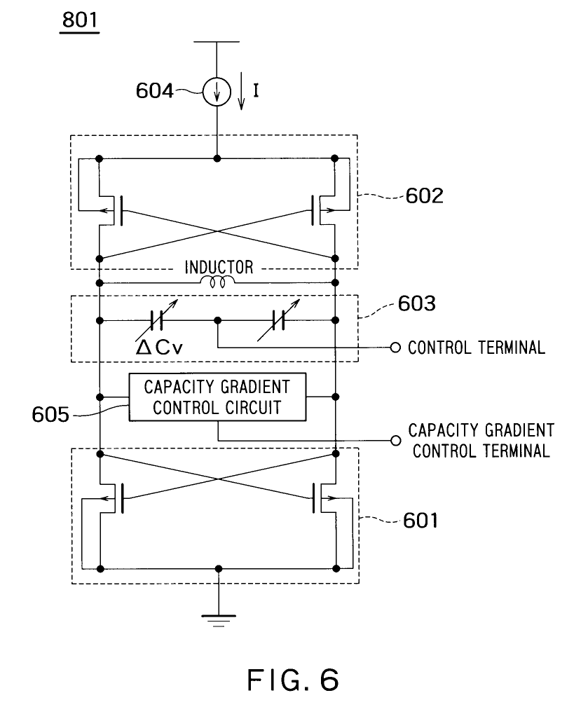

FIG. 6 is a circuit diagram showing a configuration of LC-VCO which is an example of VCO 801 of the second embodiment of the present invention.

In addition to the configuration similar to that of the first embodiment of the present invention (an NMOS transistor pair 601, a PMOS transistor pair 602, a varactor 603, and a current source 604), VCO 801 of the second embodiment of the present invention includes a capacity gradient control circuit (characteristic control unit) 605 which controls a relationship (capacity characteristic) between the bias current I and a capacity change ΔCt using a capacity gradient control signal supplied from a capacity gradient control terminal.

It is assumed that Cg is a capacity of the capacity gradient control circuit 605 and ΔCg is a fluctuation amount of the capacity of the capacity gradient control circuit 605 when the noise ΔI of the bias current is generated. ΔCg is controlled by the capacity gradient control signal. Similarly to the first embodiment of the present invention, it is assumed that Cn, Cp, and Cv are capacities of the NMOS transistor pair 601, PMOS transistor pair 602, and varactor 603 at arbitrary bias current I. The capacities Cn, Cp, and Cv fluctuates by the noise ΔI of the bias current, and a total fluctuation capacity ΔCt becomes ΔCg+ΔCn+ΔCp+ΔCv.

The capacity gradient control circuit 605 controls ΔCg such that the total fluctuation capacity ΔCt becomes zero to reduce the phase noise caused by a noise of an arbitrary bias current I. For example, the capacity gradient control circuit 605 is formed by a MOS varactor or a junction type varactor.

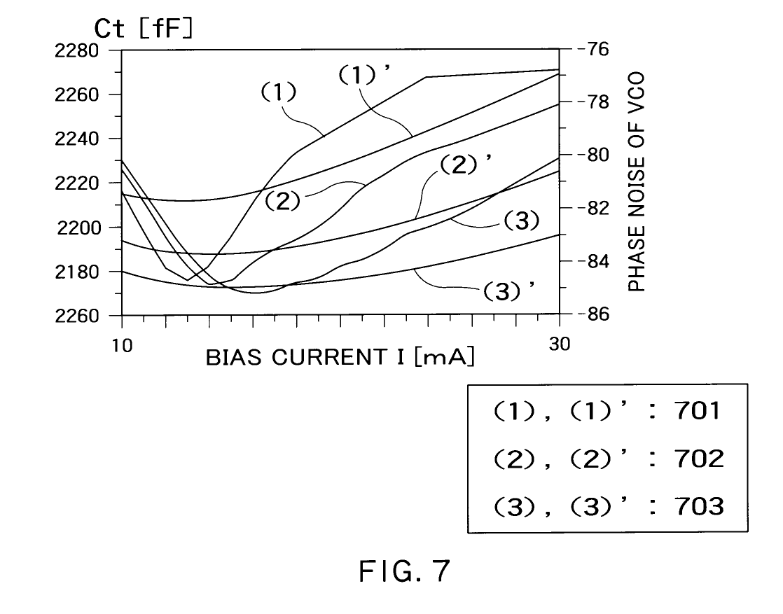

FIG. 7 is a graph showing a relationship between the total capacity Ct (=Cg+Cn+Cp+Cv) and the bias current I and a relationship between the phase noise of VCO and the bias current I when the capacity gradient control device 605 formed by the MOS varactor of the second embodiment of the present invention is used.

FIG. 7 shows characteristics ((1) to (3) and (1)′ to (3)′) corresponding to three kinds of capacity gradient control signals 701 to 703 respectively. When the capacity gradient control signal is changed, the bias current I in which the total capacity Ct becomes the minimum is changed, and therefore the bias current I in which the VCO phase noise becomes the lowest is changed (the point at which the noise caused by the change in bias current I has no influence on the phase noise).

For example, when the capacity gradient control circuit 605 supplies the capacity gradient control signal 701, the relationship between the total capacity Ct and the bias current I becomes the relationship (1), and the relationship between the VCO phase noise and the bias current I becomes the relationship (1)′.

When the capacity gradient control circuit 605 changes the capacity gradient control signal 701 into capacity gradient control signal 702, the relationship between the total capacity Ct and the bias current I becomes the relationship (2), and the relationship between the VCO phase noise and the bias current I becomes the relationship (2)′. As a result, the bias current I in which the total capacity Ct becomes the minimum is increased and the minimum value is decreased.

When the capacity gradient control circuit 605 changes the capacity gradient control signal 702 into the capacity gradient control signal 703, the relationship between the total capacity Ct and the bias current I becomes the relationship (3), and the relationship between the VCO phase noise and the bias current I becomes the relationship (3)′. As a result, the bias current I in which the total capacity Ct becomes the minimum is further increased and the minimum value is further decreased.

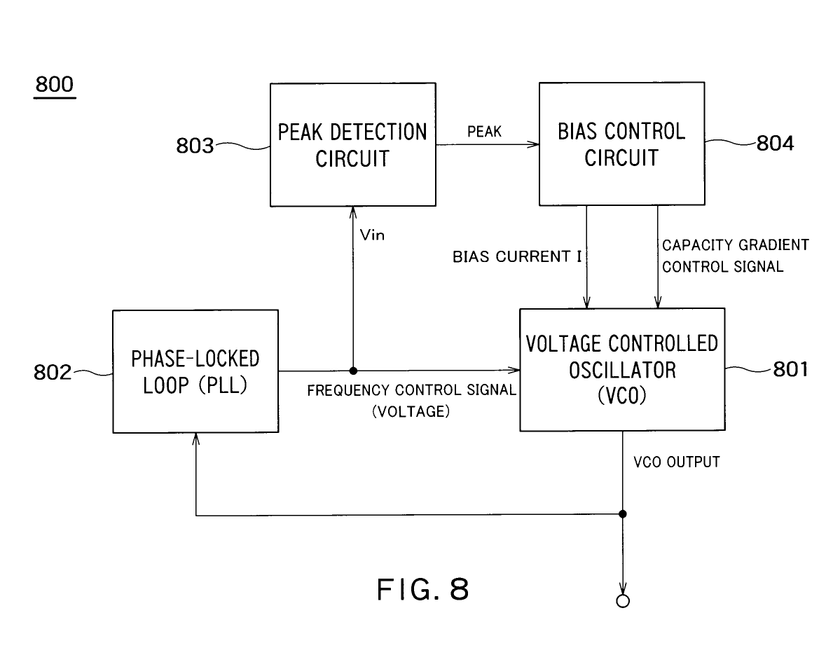

FIG. 8 is a block diagram showing a configuration of a semiconductor integrated circuit device 800 of the second embodiment of the present invention.

Similarly to the semiconductor integrated circuit device 300 of the first embodiment of the present invention, the semiconductor integrated circuit device 800 of the second embodiment of the present invention includes a voltage controlled oscillator (VCO) 801, a Phase-Locked Loop (PLL) circuit 802, a peak detection circuit 803, and a bias control circuit 804.

An operation of the semiconductor integrated circuit device 800 of the second embodiment of the present invention will be described.

The bias control circuit 804 sets the capacity gradient control signal to a predetermined small value, and the bias control circuit 804 sets the bias current I of VCO 801 to a value (I1−2ΔI1) which is slightly smaller than a desired current. Then, the bias control circuit 804 supplies the capacity gradient control signal and the bias current I. The PLL circuit 802 and the peak detection circuit 803 are similar to those of the first embodiment of the present invention.

Then, the bias control circuit 804 slightly increases the bias current to set the bias current to I1−ΔI1. Similarly to the first embodiment of the present invention, the peak detection circuit 803 compares the new frequency control signal value (Vin′) and the previously-retained frequency control signal value (Vin), and the peak detection circuit 803 makes the determination of the peak on the basis of the comparison result.

Then, the bias control circuit 804 slightly increases the bias current I to set the bias current I to a desired current value I1. Similarly the peak detection circuit 803 compares the new frequency control signal value (Vin′) and the previously-retained frequency control signal value (Vin), and the peak detection circuit 803 makes the determination of the peak on the basis of the comparison result.

When the same determination result is obtained in the two consecutive determinations, the bias control circuit 804 slightly increases the capacity gradient control signal to set the bias current I of VCO 801 to the value (I1−2ΔI1) which is slightly smaller than the desired current again, and the bias control circuit 804 supplies the bias current I. Then, the bias control circuit 804 performs the increase in bias current I ((I1−2ΔI1) and I1) and twice determinations.

The bias control circuit 804 repeats the increase in capacity gradient control signal until the second determination result is inverted to the first determination result. Finally the bias control circuit 804 fixes the bias current I to the capacity gradient control signal in which the second determination result is inverted to the first determination result, and the bias control circuit 804 supplies the fixed bias current I.

According to the second embodiment of the present invention, when the steady-state current (I1) is supplied from the current source 804, the bias control circuit 804 supplies the bias current I to the noise ΔI generated from the noise generating element except for the current source 804 such that the total capacity Ct does not fluctuate, so that the VCO phase noise caused by the noise of the noise generating element except for the current source can be reduced in addition to the same effect as the first embodiment of the present invention.

### Third Embodiment

A third embodiment of the present invention will be described below. In the second embodiment of the present invention, the bias current is directly controlled according to the capacity gradient control signal in order to reduce the VCO phase noise caused by the noise of the noise generating element except for the current source. On the other hand, in the third embodiment of the present invention, the bias current is controlled by adjusting a back-gate voltage. The same description as the first and second embodiments of the present invention is not repeated.

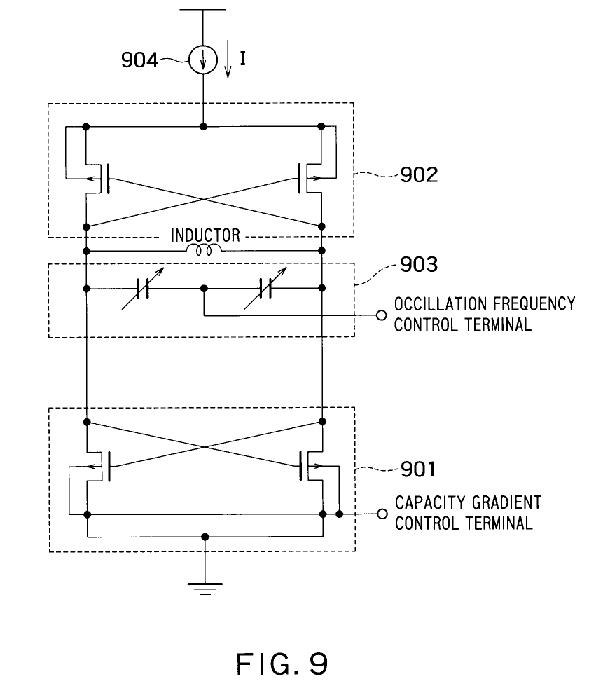

FIG. 9 is a circuit diagram showing a configuration of LC-VCO which is an example of VCO of the third embodiment of the present invention.

VCO of the third embodiment of the present invention has the configuration similar to that of the first embodiment of the present invention (an NMOS transistor pair 901, a PMOS transistor pair 902, a varactor 903, and a current source 904).

The NMOS transistor pair 901 is connected to a capacity gradient control terminal. The capacity Cn of the NMOS transistor pair 901 is controlled by the capacity gradient control signal. The PMOS transistor pair 902 and the varactor 903 have the same configuration as those of the second embodiment of the present invention.

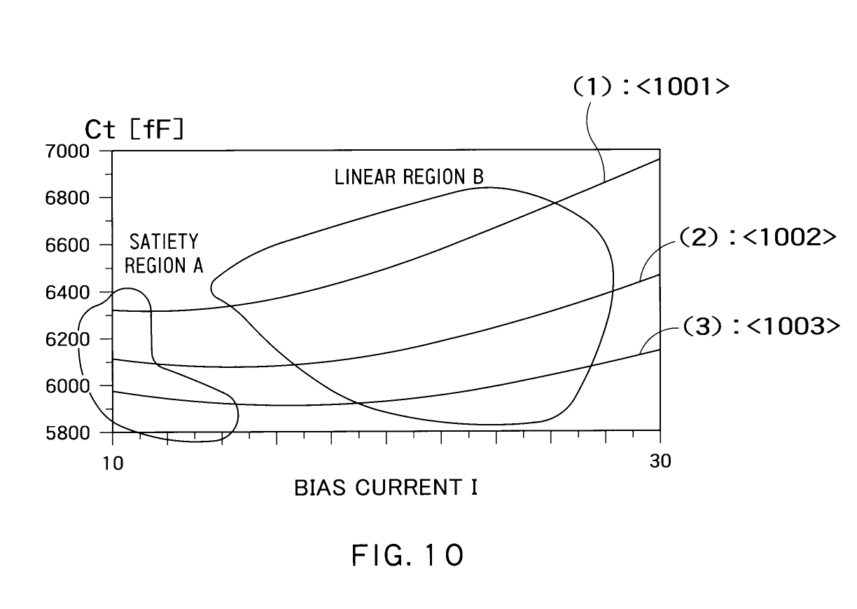

FIG. 10 is a graph showing a relationship between the bias current I and the total capacity Ct (=Cn+Cp+Cv) corresponding to back-gate voltages of capacity gradient control signals 1001 to 1003.

For example, when a bias control circuit 1104 supplies the capacity gradient control signal 1001, the relationship between the total capacity Ct and the bias current I becomes a relationship (1).

When the bias control circuit 1104 changes the capacity gradient control signal 1001 into the capacity gradient control signal 1002, the relationship between the total capacity Ct and the bias current I becomes a relationship (2). As a result, similarly to the second embodiment of the present invention, the bias current I in which the total capacity Ct becomes the minimum is increased and the minimum value of the phase noise is decreased.

When the bias control circuit 1104 changes capacity gradient control signal 1002 into the capacity gradient control signal 1003, the relationship between the total capacity Ct and the bias current I becomes a relationship (3). As a result, similarly to the second embodiment of the present invention, the bias current I in which the total capacity Ct becomes the minimum is further increased and the minimum value of the phase noise is further decreased.

As shown in FIG. 10, in a saturation region A, the capacity Cn of the NMOS transistor pair 901 is decreased as the bias current I is increased. On the other hand, in a linear region B, the capacity Cn of the NMOS transistor pair 901 is increased as the bias current I is increased. That is, in the NMOS transistor pair 901 of the third embodiment of the present invention, the back-gate voltage is adjusted to control the bias current I in the linear region B, thereby performing the capacity gradient control.

According to the third embodiment of the present invention, the back-gate voltage is adjusted to control the bias current I. Thus, the same effect as the second embodiment of the present invention can be obtained while the configuration corresponding to the capacity gradient control circuit 605 of the second embodiment of the present invention is eliminated, and therefore the configuration of the semiconductor integrated circuit device can be simplified.

### Fourth Embodiment

A fourth embodiment of the present invention will be described below. In the first to third embodiments of the present invention, the VCO phase noise is reduced using the frequency control signal value supplied from the PLL circuit 302 or 802. On the other hand, in the fourth embodiment of the present invention, the VCO phase noise is reduced using a counted value of a frequency counter. The same description as the first to third embodiments of the present invention is not repeated.

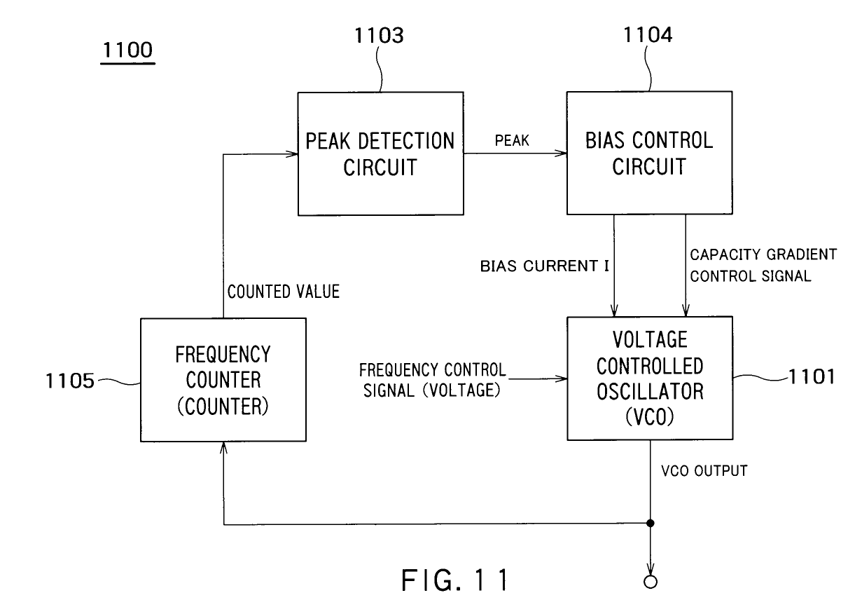

FIG. 11 is a block diagram showing a configuration of a semiconductor integrated circuit device 1100 of the fourth embodiment of the present invention.

The semiconductor integrated circuit device 1100 of the fourth embodiment of the present invention includes a VCO 1101, a peak detection circuit 1103, a bias control circuit 1104, and a frequency counter (counter) 1105.

An operation of the semiconductor integrated circuit device 1100 of the fourth embodiment of the present invention will be described. In the semiconductor integrated circuit device 1100 of the fourth embodiment of the present invention, because the configuration corresponding to the PLL circuit 302 or 802 of FIG. 3 or 8 is eliminated, the frequency control signal of VCO 1101 is fixed to a predetermined value.

The bias control circuit 1104 increases the bias current I of VCO 1101. The counter 1105 measures the oscillation frequency of the VCO output of VCO 1101 to supply a counted value. The peak detection circuit 1103 detects an oscillation frequency peak (maximum or minimum) of the VCO output of VCO 1101 on the basis of the counted value supplied from the counter 1105, and the peak detection circuit 1103 supplies the detection result (peak). Similarly to the first embodiment of the present invention, the bias control circuit 1104 fixes the bias current I to the peak supplied from the peak detection circuit 1103.

According to the fourth embodiment of the present invention, the peak detection circuit 1103 detects the peak on the basis of the counted value supplied from the counter 1105. Therefore, the same effect as the first to third embodiment of the present invention is obtained even if the frequency control signal fed into VCO 1101 is kept constant. Additionally, the circuit configuration corresponding to the PLL circuit 302 or 802 of FIG. 3 or 8 can be eliminated, and therefore the configuration of the semiconductor integrated circuit device can be simplified.

What is claimed is:

1. A semiconductor integrated circuit device comprising:
a voltage controlled oscillator which controls a bias current or an oscillation frequency to supply an output signal;
a phase-locked loop circuit which supplies a frequency control signal based on the output signal supplied from the voltage controlled oscillator;
a peak detection circuit which detects a peak of the frequency control signal supplied from the phase-locked loop circuit; and
a bias control circuit which produces a bias current based on the peak detected by the peak detection circuit to supply the bias current,
wherein the voltage controlled oscillator controls the bias current supplied from the bias control circuit or the oscillation frequency to supply the output signal based on the frequency control signal supplied from the phase-locked loop circuit.

2. The semiconductor integrated circuit device according to claim 1, wherein the voltage controlled oscillator includes a characteristic control unit which controls a capacity characteristic of the voltage controlled oscillator based on the bias control signal supplied from the bias control circuit.

3. The semiconductor integrated circuit device according to claim 2, wherein the characteristic control unit is a MOS varactor.

4. The semiconductor integrated circuit device according to claim 2, wherein the voltage controlled oscillator further includes a transistor, and
the characteristic control unit controls a back-gate voltage applied to the transistor based on the capacity characteristic of the voltage controlled oscillator.

5. The semiconductor integrated circuit device according to claim 3, wherein the voltage controlled oscillator further includes a transistor, and
the characteristic control unit controls a back-gate voltage applied to the transistor based on the capacity characteristic of the voltage controlled oscillator.

6. A semiconductor integrated circuit device comprising:
a voltage controlled oscillator which controls a bias current or an oscillation frequency to supply an output signal based on a constant frequency control signal;
a frequency counter which measures an oscillation frequency of the output signal supplied from the voltage controlled oscillator;
a peak detection circuit which detects a peak of the output signal based on a counted value supplied from the frequency counter; and
a bias control circuit which produces a bias current based on the peak detected by the peak detection circuit to supply the bias current,
wherein the voltage controlled oscillator controls the bias current or oscillation frequency to supply the output signal based on the bias current supplied from the bias control circuit.

7. The semiconductor integrated circuit device according to claim 6, wherein the bias control circuit fixes the bias current to the peak supplied from the peak detection circuit.

8. The semiconductor integrated circuit device according to claim 6, wherein the voltage controlled oscillator includes a characteristic control unit which controls a capacity characteristic of the voltage controlled oscillator based on the bias control signal supplied from the bias control circuit.

9. The semiconductor integrated circuit device according to claim 8, wherein the characteristic control unit is a MOS varactor.

10. The semiconductor integrated circuit device according to claim 8, wherein the voltage controlled oscillator further includes a transistor, and
the characteristic control unit controls a back-gate voltage applied to the transistor based on the capacity characteristic of the voltage controlled oscillator.

11. The semiconductor integrated circuit device according to claim 9, wherein the voltage controlled oscillator further includes a transistor, and
the characteristic control unit controls a back-gate voltage applied to the transistor based on the capacity characteristic of the voltage controlled oscillator.
